(19) United States
(12) Patent Application Publication
(10) Pub. No.: US 2008/0032431 A1
(43) Pub. Date: Feb. 7, 2008

(54) Method for fabricating a system for displaying images

(75) Inventors: Kuo-Bin Hsu, Lugang Township (TW); Chun-Yen Liu, Jhubei City (TW); Yi-Fan Shih, Taipei City (TW); Chang-Ho Tseng, Sinwu Township (TW); Shih-Chang Chang, Jhudong Township (TW)

Correspondence Address: LIU & LIU, 444 S. FLOWER STREET, SUITE 1750, LOS ANGELES, CA, 90071, US

(73) Assignee: TPO Displays Corp.

(21) Appl. No.: 11/499,118

(22) Filed: Aug. 3, 2006

(51) Int. Cl. H01L 21/00

(52) U.S. Cl. 438/29

(57) ABSTRACT

The invention provides a method for manufacturing systems for displaying images. A representative system incorporates electroluminescent devices, comprising the following steps. A substrate having an active region and a pad region is provided. A thin film transistor is formed on the active region and a pad electrode is formed on the pad region, wherein the thin film transistor comprise a source electrode, a gate electrode, a drain electrode, and a gate insulator. A protective layer is formed on the active region and pad region. A planarization layer is formed on the active region and pad region, after forming color filter patterns on the protective layer on the active region. A first contact hole is formed to pass through the planarization layer of the active region, exposing the surface of the protective layer directly on the drain electrode. A drain via hole is formed to pass through the protective layer of the active region after the formation of the color filter patterns and the planarization layer, exposing the drain electrode. A pad via hole is formed to pass through the protective layer of the pad region after the formation of planarization layer, exposing the pad electrode.

### BACKGROUND OF THE INVENTION

1. Field of the Invention

The invention relates to a method for fabricating a system for displaying images, and in particular to a method for fabricating a system comprising electroluminescent devices with color filter on array (COA) process.

2. Description of the Related Art

In accordance with driving methods, an organic light emitting display (OLED) is an active matrix type or a positive matrix type. The active matrix OLED (AM-OLED) is driven by electric currents, in which each of the matrix-array pixel areas has at least one thin film transistor (TFT), serving as a switch, to modulate the driving current based on the variation of capacitor storage potential so as to control the brightness and gray level of the pixel areas.

FIGS. 1a to 1e are a series of cross sections illustrating the process flow of the conventional organic electroluminescent device with color filter. Referring to FIG. 1a, a substrate 10 with an active region 11 and a pad region 12 is provided, wherein a thin film transistor 13 is formed on the active region 11 and a metal pad 14 is formed on the pad region 12. An isolation layer 15 is formed on the substrate 10.

Next, referring to FIG. 1b, the isolation layer 15 is patterned to form a drain via hole 16 and a pad via hole 17. The drain via hole 16 exposes a drain electrode 18 of the thin film transistor 13 and the pad via hole 17 exposes the metal pad 14.

Next, referring to FIG. 1c, a color filter layer 19 is formed on the active region 11 by photography. It should be noted the color filter layer 19 directly contacts the drain electrode 18 and metal pad 14 through the drain via hole 16.

Next, referring to FIG. 1d, the color filter layer is patterned to form color filter patterns 20, and then a planarization layer 21 is formed on the substrate 10. In this step, the planarization layer 21 directly contacts the drain electrode 18 and metal pad 14 through the drain via hole 16 and pad via hole 17. Finally, referring to FIG. 1e, the planarization layer 21 is patterned, exposing the drain electrode 18 and the pad metal 14.

The conventional process, since the color filter layer and/or the planarization layer directly contact the drain electrode through the drain via hole, the electrode of the thin film transistor can be damaged by electrostatic discharge (ESD). Further, due to the larger surface area of metal pad, the color filter layer and/or the planarization layer directly contacting therewith may create an antenna effect, enlarging damage from electrostatic discharge.

Therefore, a novel method for manufacturing full-color electroluminescent devices, preventing electrostatic discharge damages is desirable.

### BRIEF SUMMARY OF THE INVENTION

Methods for fabricating a system for displaying images are provided. An exemplary embodiment of a method for fabricating a system comprising electroluminescent devices for displaying images comprises the following steps. A substrate having an active region and a pad region is provided. A thin film transistor is formed on the active region and a pad electrode is formed on the pad region, wherein the thin film transistor comprise a source electrode, a gate electrode, a drain electrode, and a gate insulator. A protective layer is formed on the active region and pad region. The color filter patterns are formed on the protective layer on the active region, wherein the color filter patterns are separated by the first contact holes over the drain electrode. A planarization layer is formed on the active region and pad region. A second contact hole is formed to pass through the planarization layer of the active region, exposing the surface of the protective layer directly on the drain electrode. A third contact hole is formed to pass through the planarization layer of the pad region, exposing the surface of the protective layer directly on the pad electrode. A drain via hole is formed to pass through the protective layer of the active region after the formation of color filter patterns and planarization layer, exposing the drain electrode. A pad via hole is formed to pass through the protective layer of the pad region after the formation of planarization layer, exposing the pad electrode.

In some embodiments of a method for fabricating a system for displaying images, a substrate having a thin film transistor is provided, wherein the thin film transistor comprise a source electrode, a gate electrode, a drain electrode, and a gate insulator. A protective layer, color filter patterns, and a planarization layer are sequentially formed on the substrate, wherein the color filter patterns are separated by the first contact holes over the drain electrode. A second contact hole is formed to pass through the planarization layer, exposing the surface of the protective layer directly on the drain electrode. A drain via hole is formed to pass through the protective layer after the formation of color filter patterns and planarization layer, exposing the drain electrode.

Some embodiments of a method for fabricating a system for displaying images comprise providing a substrate having a pad electrode. A protective layer and a planarization layer are sequentially formed to cover the pad electrode. A contact hole is formed to pass through the planarization layer, exposing the surface of the protective layer directly on the pad electrode. A pad via hole is formed to pass through the protective layer after the formation of planarization layer, exposing the pad electrode.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1a to 1e are crosssections of a conventional method for fabricating electroluminescent devices;

FIG. 2 is a top view illustrating the pixel structure of an embodiment of an active matrix substrate employed in a flat panel display; and

FIGS. 3a to 3h are crosssections of an embodiment of a method for fabricating electroluminescent devices with the COA process.

FIG. 4 schematically shows another embodiment of a system for displaying images.

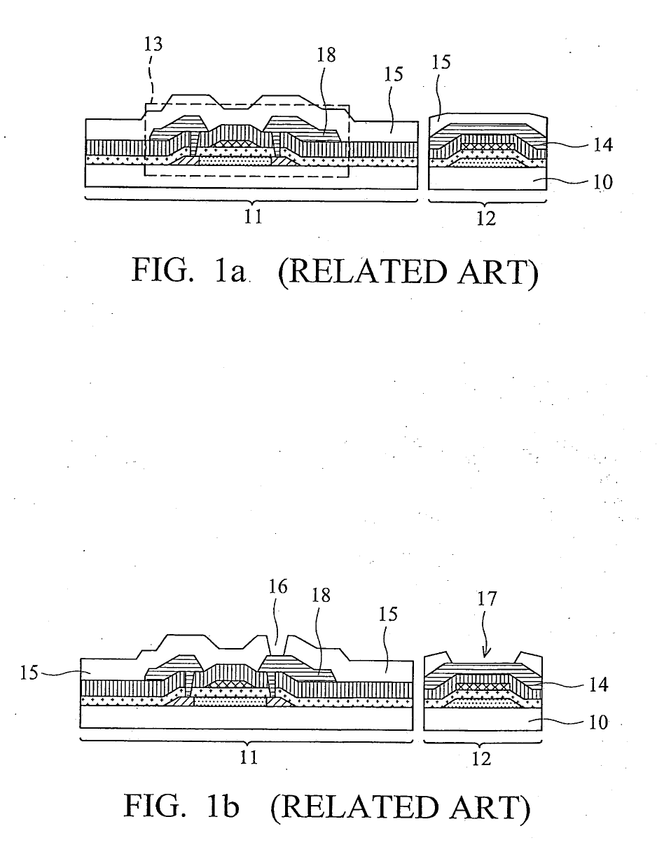

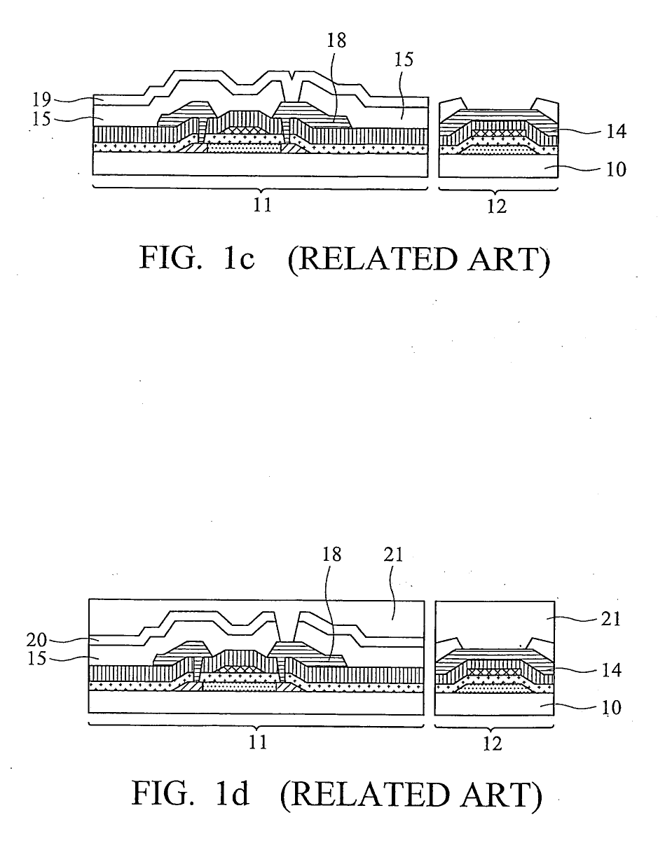

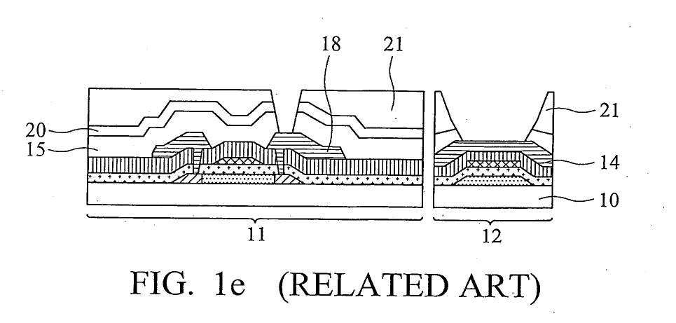

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

A method for manufacturing electroluminescent devices with the COA process prevents the color filter layer, the planarization, and photoresists from directly contacting the metal conductive layer (i.e. drain electrode and pad electrode), thereby protective the thin film transistor against electrostatic discharge. Thus, the yield of the fabrication process is improved.

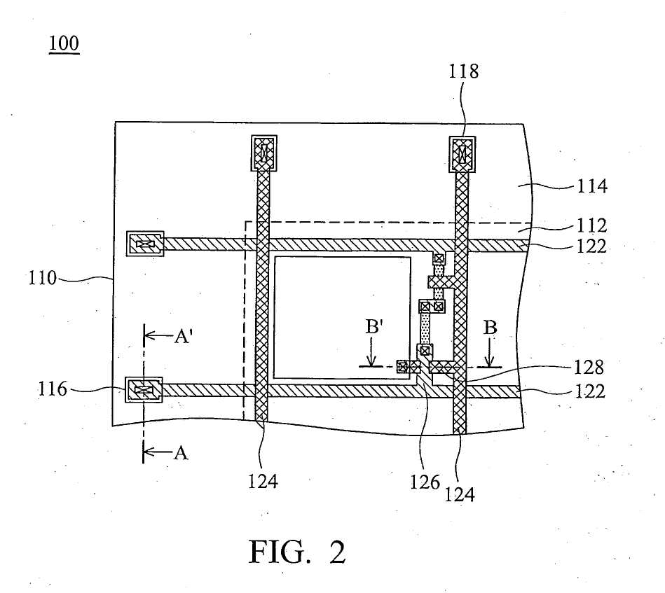

FIG. 2 is a partial top view of an embodiment of an electroluminescent device comprising an active matrix substrate. The active matrix substrate comprises a substrate 110 which is defined as an active region 112, and a pad region 114. Gate pads 116 and data pads 118 are formed in the pad region 114, wherein the gate pads 116 electrically connect to a gate electrode 126 through a gate line 122, and the data pads 118 electrically connect to a source electrode 128 through a data line 124.

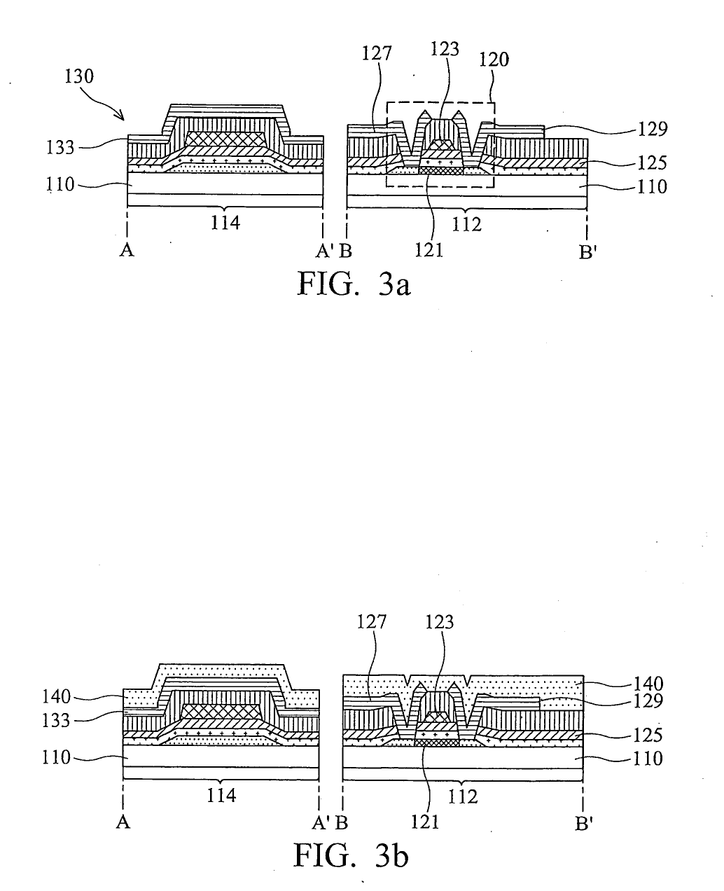

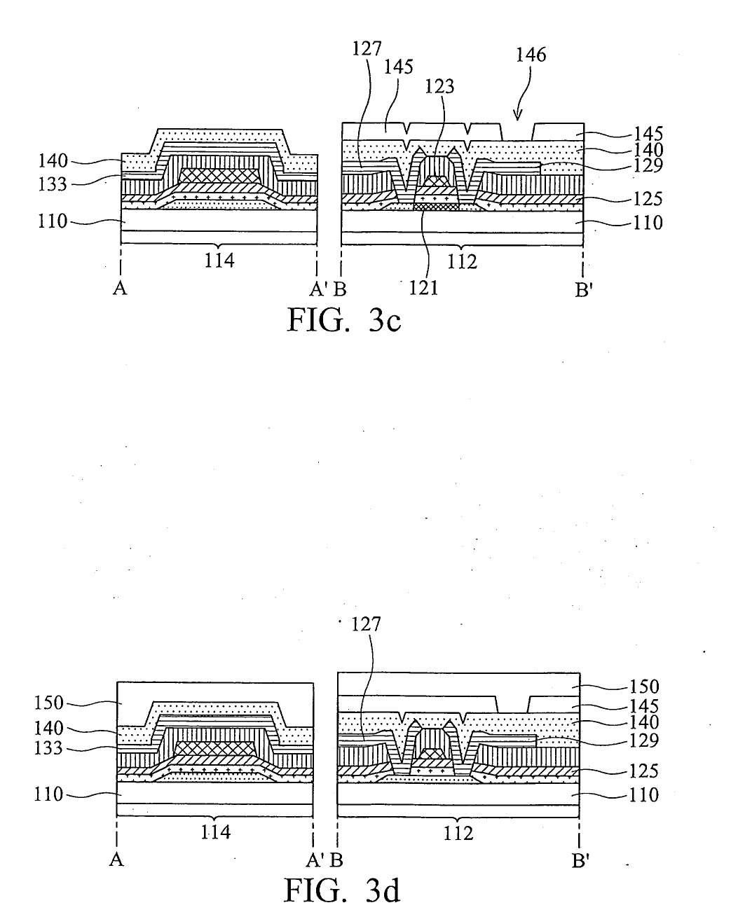

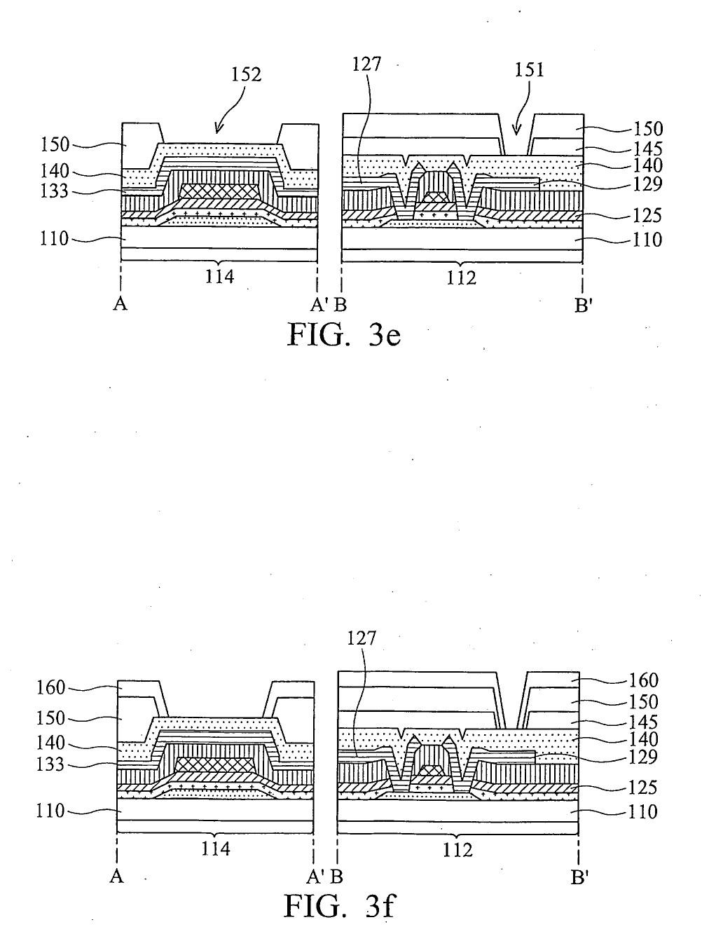

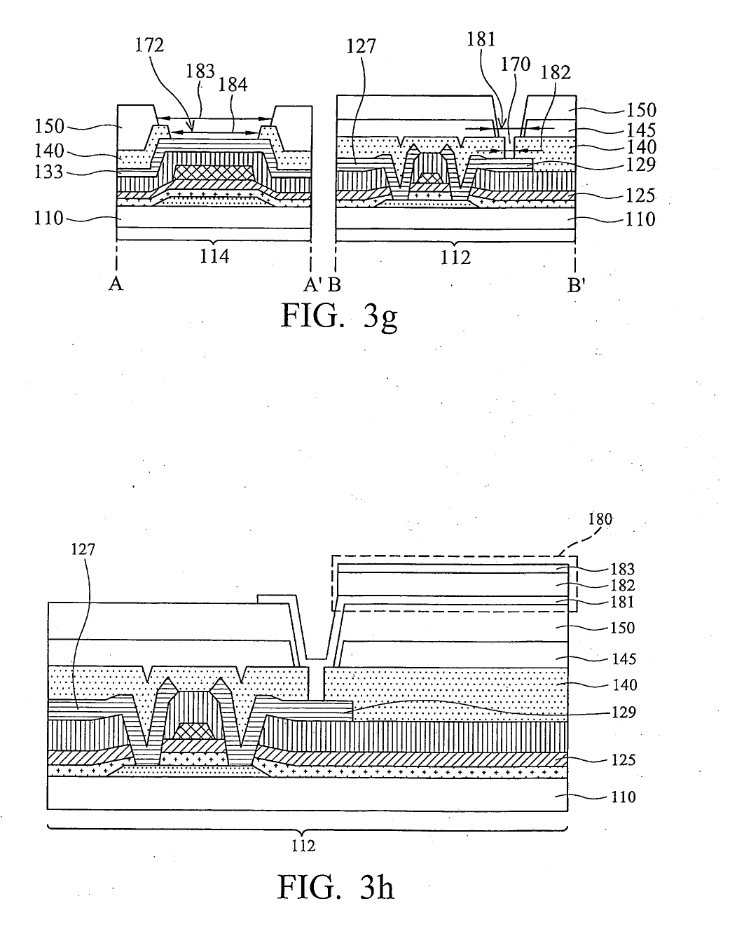

FIGS. 3a to 3h are sectional diagrams of FIG. 2 along lines A-A′ and B-B′, showing the method for fabricating electroluminescent devices.

First, referring to FIG. 3a, the substrate 110 with the active region 112 and the pad region 114 is provided. A thin film transistor (TFT) 120 is formed on the active region 112 and a pad structure 130 is formed on the pad region 114. The thin film transistor 120 comprises a semiconductor layer 121, a gate electrode 123, a gate insulator 125, a source electrode 127, and a drain electrode 129, and the pad structure 130 comprise a pad electrode 133. The thin film transistor 120 can be an amorphous-silicon thin film transistor, low temperature poly-silicon thin film transistor (LTPS-TFT), organic thin film transistor (OTFT), or others. The structure of the thin film transistor 120 illustrated is an example, and is not intended to be limitative of the invention. Herein, the gate insulator 125 can be a silicon nitride, and the substrate 110 can be a transparent insulating material such as glass or plastic. Further, the source electrode 127 and drain electrode 129, and pad electrode 133 can be of the same material and formed by the same process

Next, referring to FIG. 3b, a protective layer 140 is completely formed on the substrate 110 to cover the thin film transistor 120 and the pad structure 130. Suitable material of the protective layer 140 can comprise silicon nitride, silicon oxide, BPSG, PSG or organic resin film.

Next, referring to FIG. 3c, color filter patterns 145 are formed on the protective layer 140 of the active region 112, wherein the color filter patterns 145 are separated by first contact holes 146. The color filter patterns 145 can comprise red, green, or blue color-filtering units, to achieve a full-color display. Since the protective layer 140 completely covers the drain electrode 129 and pad electrode 133, no color filter or photoresist directly contacts the metal conductive layer (drain electrode 129 and pad electrode 133) during the step of forming color filter patterns 145.

Next, referring to FIG. 3d, a planarization layer 150 is blanketly formed on the substrate 110. Herein, the planarization layer 150 can be SiOx, SiNx (x≧1), spin-on glass (SOG) or insulating organic compound. It should be noted that the planarization layer 150 and the metal conductive layer (drain electrode 129 and pad electrode 133) are separated by the protective layer 140.

Next, referring to FIG. 3e, the planarization layer 150 is patterned to form a second contact hole 151 and a third contact hole 152 passing therethrough. The second contact hole 151 exposes the surface of the protective layer 140 directly on the drain electrode 129, and the third contact hole 152 exposes the surface of the protective layer 140 directly on the pad electrode 133. Wherein, the second contact hole and the third contact hole are formed by the same process.

Next, referring to FIG. 3f, a photoresist layer 160 is formed on the planarization layer 150. Specifically, the photoresist layer 160 is formed on the side wall of the planarization layer in the second and third contact holes 151 and 152. The protective layer is etched with the photoresist layer 160 acting as a mask, forming a drain via hole 170 and a pad via hole 172, resulting in the second and third contact holes directly lying on the drain and pad via hole respectively. Referring to FIG. 3g, the photoresist layer 160 is then removed. The drain via hole 170 exposes the drain electrode 129, and the pad via hole 172 exposes the pad electrode 133. Specifically, the drain via hole 170 and the pad via hole 172 are formed by the same process after the formation of the color filter patterns 145 and the planarization layer 150. It should be noted that the size 181 of the second contact hole 151 is larger than the size 182 of the drain via hole 170, casing the first contact hole 146 exposing the top surface of the protective layer 140 around the drain via hole 170. Further, the size 183 of the third contact hole 152 is larger than the size 184 of the pad via hole, casing the third contact hole 152 exposing the top surface of the protective layer 140 around the pad via hole 172.

Referring to FIG. 3h, an organic light emitting diode 180 is formed on the planarization layer 150, wherein organic light emitting diode 180 comprises an anode electrode 181, electroluminescent layers 182, and a cathode electrode 183. Specifically, the anode electrode 181 is electrically connected to the drain electrode 129. Thus, fabrication of the thin film transistor is completed. In an embodiment of the invention, the organic light-emitting diode exhibits white emission.

Since the color filter layer, planarization layer and photoresist layer do not directly contact the drain electrode (or the pad electrode) through the drain via hole (or pad via hole), electrostatic discharge (ESD) damage to the electrode of the thin film transistor can be prevented.

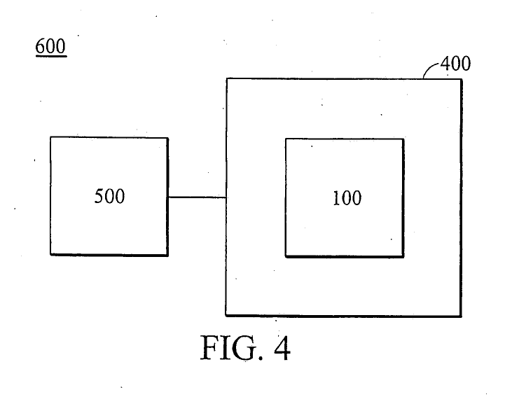

FIG. 4 schematically shows another embodiment of a system for displaying images which, in this case, is implemented as a display panel 400 or an electronic device 600. The described active matrix organic electroluminescent device can be incorporated into a display panel that can be an OLED panel. As shown in FIG. 4, the display panel 400 comprises an active matrix organic electroluminescent device, such as the active matrix organic electroluminescent device 100 shown in FIG. 2. The display panel 400 can form a portion of a variety of electronic devices (in this case, electronic device 600). Generally, the electronic device 600 can comprise the display panel 400 and an input unit 500. Further, the input unit 500 is operatively coupled to the display panel 400 and provides input signals (e.g., an image signal) to the display panel 400 to generate images. The electronic device 600 can be a mobile phone, digital camera, PDA (personal data assistant), notebook computer, desktop computer, television, car display, or portable DVD player, for example.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of fabricating a system for displaying images, wherein the system comprising electroluminescent devices, the method comprising:
providing a substrate having an active region and a pad region;
forming a thin film transistor on the active region and a pad electrode on the pad region, wherein the thin film transistor comprise a source electrode, a gate electrode, a drain electrode, and a gate insulator;
forming a protective layer on the active region and pad region;
forming color filter patterns on the protective layer on the active region, wherein the color filter patterns are separated by first contact holes over the drain electrode;
forming a planarization layer on the active region and pad region;
forming a second contact hole passing through the planarization layer of the active region, exposing the surface of the protective layer directly on the drain electrode;
forming a third contact hole passing through the planarization layer of the pad region, exposing the surface of the protective layer directly on the pad electrode;
forming a drain via hole passing through the protective layer of the active region after the formation of color filter patterns and planarization layer, exposing the drain electrode; and
forming a pad via hole passing through the protective layer of the pad region after the formation of planarization layer, exposing the pad electrode.

2. The method as claimed in claim 1, further comprising
forming an organic light-emitting diode on the active region, wherein an anode of the organic light-emitting diode electrically connects the drain electrode through the second contact hole and the drain via hole.

3. The method as claimed in claim 1, wherein the size of the second contact hole is larger than the size of the drain via hole, and the second contact hole exposes the top surface of the protective layer after forming the drain via hole.

4. The method as claimed in claim 1, wherein the size of the third contact hole is larger than the size of the pad via hole, and the third contact hole exposes the top surface of the protective layer after forming the pad via hole.

5. The method as claimed in claim 1, wherein the first contact hole directly lies on the drain via hole.

6. The method as claimed in claim 1, wherein the third contact hole directly lies on the pad via hole.

7. The method as claimed in claim 1, wherein the second contact hole and the third contact hole are formed by the same process.

8. The method as claimed in claim 1, wherein the drain via hole and the pad via hole are formed by the same process.

9. A method of fabricating a system for displaying images, wherein the system comprising electroluminescent devices, the method comprising:
providing a substrate having a thin film transistor, wherein the thin film transistor comprises a source electrode, a gate electrode, a drain electrode, and a gate insulator;
sequentially forming a protective layer, color filter patterns, and a planarization layer on the substrate, wherein the color filter patterns are separated by first contact holes over the drain electrode;
forming a second contact hole passing through the planarization layer, exposing the surface of the protective layer directly on the drain electrode; and
forming a drain via hole passing through the protective layer after the formation of color filter patterns and planarization layer, exposing the drain electrode.

10. The method as claimed in claim 9, further comprising
forming an organic light-emitting diode, wherein an anode of the organic light-emitting diode electrically connects the drain electrode through the contact hole and the drain via hole.

11. The method as claimed in claim 9, wherein the size of the second contact hole is larger than the size of the drain via hole, and the secondt contact hole exposes the top surface of the protective layer after forming the drain via hole.

12. The method as claimed in claim 9, wherein the first contact hole directly lies on the drain via hole.

13. The method as claimed in claim 9, wherein the protective layer comprises silicon nitride, silicon oxide, BPSG, PSG or organic resin film.

14. A method of fabricating a system for displaying images, wherein the system comprising electroluminescent devices, the method comprising:
providing a substrate having a pad electrode;
sequentially forming a protective layer and a planarization layer covering the pad electrode;
forming a contact hole passing through the planarization layer, exposing the surface of the protective layer directly on the pad electrode; and
forming a pad via hole passing through the protective layer after the formation of planarization layer, exposing the pad electrode.

15. The method as claimed in claim 14, wherein the size of the contact hole is larger than the size of the pad via hole, and the contact hole exposes the top surface of the protective layer after forming the pad via hole.

16. The method as claimed in claim 14, wherein the contact hole directly lies on the pad via hole.

17. The method as claimed in claim 14, wherein the protective layer comprises silicon nitride, silicon oxide, BPSG, PSG or organic resin film.
